(19) United States
(12) Patent Application Publication
(10) Pub. No.: US 2018/0179424 A1
(43) Pub. Date: Jun. 28, 2018

(54) ADHESIVE COMPOSITION AND COMPOSITE SUBSTRATE EMPLOYING THE SAME

(71) Applicant: INDUSTRIAL TECHNOLOGY RESEARCH INSTITUTE, Hsinchu (TW)

(72) Inventors: Jyh-Long JENG, New Taipei City (TW); Jeng-Yu TSAI, Chiayi City (TW); Hsi-Yi CHIN, Hsinchu City (TW); Wei-Ta YANG, Taoyuan City (TW)

(73) Assignee: INDUSTRIAL TECHNOLOGY RESEARCH INSTITUTE, Hsinchu (TW)

(21) Appl. No.: 15/656,652

(22) Filed: Jul. 21, 2017

(30) Foreign Application Priority Data
Dec. 23, 2016 (TW) 105142917

(51) Int. Cl. C09J 171/12; C09J 153/00; H05K 1/02; H05K 1/03; H05K 1/09; B32B 7/12; B32B 15/08

(52) U.S. Cl. CPC C09J 171/12; C09J 153/00; H05K 1/028; B32B 2457/08; H05K 1/09; B32B 7/12; B32B 15/08; H05K 1/032

(57) ABSTRACT

An adhesive composition and a composite substrate employing the same are provided. The adhesive composition includes a compound having a structure represented by Formula (I)

(Z—Y₃X Formula (I)

, wherein X is

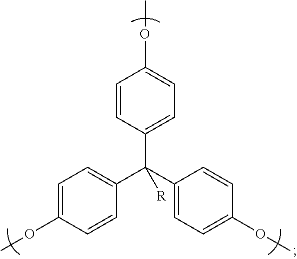

R can be hydrogen, or C₁₋₆ alkyl group; each Y can be independently a moiety polymerized by at least two different phenol-based compounds; and each Z can be independently hydrogen, acryloyl group, allyl group, vinylbenzyl group, epoxypropyl group, methylacryloyl group, propargyl group, or cyanoallyl group; a thermoplastic elastomer; an epoxy resin; and a bismaleimide.

### CROSS REFERENCE TO RELATED APPLICATIONS

The application is based on, and claims priority from, Taiwan Application Serial Number 105142917, filed on Dec. 23, 2016, the disclosure of which is hereby incorporated by reference herein in its entirety.

### TECHNICAL FIELD

The disclosure relates to an adhesive composition, and a composite substrate employing the same.

### BACKGROUND

In the field of electronic components, it is of urgent necessity for a high-frequency device to enable high-frequency operation. Therefore, electronic component-related materials (such as semiconductor sealing material having a low dielectric constant and a low dielectric dissipation factor) have recently been required, in order to enhance the data transmission speed and avoid data loss or interference.

Due to the low dielectric constant and low dielectric dissipation factor, the flexible copper clad laminate (FCCL) including liquid-crystal polymer (LCP) can serve as materials of high frequency circuit board. However, the lamination temperature of conventional liquid-crystal polymers is high, resulting in difficulties forming a multi-layer board of liquid crystal polymer (LCP) layers via lamination. Therefore, a novel material for printed circuit board process is called for.

According to embodiments of the disclosure, the disclosure provides an adhesive composition, and the adhesive composition can include a compound having a structure represented by Formula (I)

(Z—Y₃X Formula (I)

, wherein X is

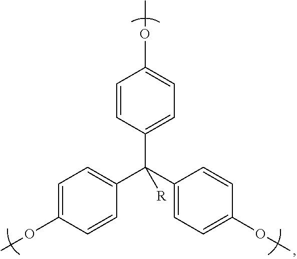

R can be hydrogen, or C₁₋₆ alkyl group; each Y can be independently a moiety polymerized by at least two different phenolic compounds; and each Z can be independently hydrogen, acryloyl group, allyl group, vinylbenzyl group, epoxypropyl group, methylacryloyl group, propargyl group, or cyanoallyl group; a thermoplastic elastomer; an epoxy resin; and a bismaleimide. In particular, the weight ratio of the compound having a structure represented by Formula (I) and the thermoplastic elastomer can range from about 1:3 to 3:1.

According to an embodiment of the disclosure, the disclosure also provides a composite substrate including an adhesive layer, wherein the adhesive layer is a cured product of the aforementioned adhesive composition; and a first substrate, wherein the adhesive layer is disposed on the first substrate.

A detailed description is given in the following embodiments with reference to the accompanying drawings.

### BRIEF DESCRIPTION OF THE DRAWINGS

FIG. 1 is a schematic view of the composite substrate according to an embodiment of the disclosure.

### DETAILED DESCRIPTION

Embodiments of the disclosure provide an adhesive composition and a composite substrate employing the same. The adhesive composition of the disclosure includes specific polyphenylene ether, thermoplastic elastomer, epoxy resin, and bismaleimide, wherein the above components are present in a determined ratio. Due to the crosslinking between the polyphenylene ether with multi-functional groups, epoxy resin, and bismaleimide, the chemical resistance of the obtained adhesive layer and the adhesion between the obtained adhesive layer and the liquid-crystal polymer (LCP) are improved. Furthermore, due to the addition of the thermoplastic elastomer, the flexibility of the adhesive layer can be enhanced. In addition, due to the determined ratio of the polyphenylene ether to the thermoplastic elastomer, the cured product of the adhesive composition of the disclosure exhibits relatively high chemical resistance and thermal resistance and relatively low dielectric constant and dielectric dissipation factor.

According to an embodiment of the disclosure, the adhesive composition can include a compound having a structure represented by Formula (I)

(Z—Y₃X Formula (I)

, wherein X is

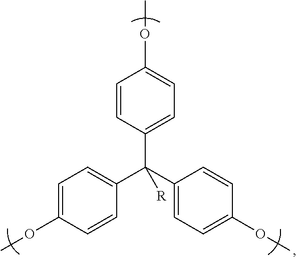

R is hydrogen, or C₁₋₆ alkyl group; each Y is independently a moiety polymerized by at least two different phenol-based compounds; and each Z is independently hydrogen, acryloyl group, allyl group, vinylbenzyl group, epoxypropyl group, methylacryloyl group, propargyl group, or cyanoallyl group; a thermoplastic elastomer; an epoxy resin; and a bismaleimide. According to an embodiment of the disclosure, the different phenols of the disclosure individually have at least one functional group, wherein the functional group is methyl group, or allyl group. For example, Y can be a moiety prepared by polymerizing 2,6-dimethylphenol and 2-allyl-6-methylphenol. In addition, Y can be

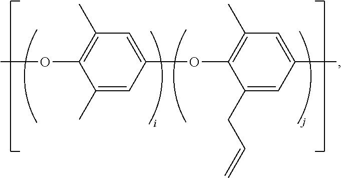

wherein i is a positive integer, j is a positive integer, and the sum of i and j is from 6 to 300, and repeat units

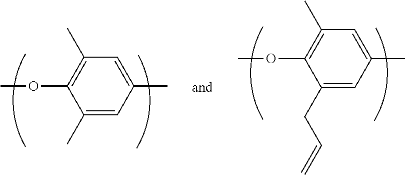

are arranged in a random or block fashion. Z can be hydrogen, epoxypropyl group, vinylbenzyl group, or methacryloyl group.

According to an embodiment of the disclosure, the compound having a structure represented by Formula (I) has a number average molecular weight from 600 to 12000, or from 1000 to 10000. When the number average molecular weight of the compound having a structure represented by Formula (I) is too low, the adhesive layer prepared from the adhesive composition exhibits low chemical resistance. When the number average molecular weight of the compound having a structure represented by Formula (I) is too high, the adhesive composition exhibits poor solubility, thereby reducing the adhesion between the obtained adhesive layer and a substrate.

According to an embodiment of the disclosure, the thermoplastic elastomer of the disclosure can be polymethyl acrylate, polymethyl methacrylate, polyacrylimide, polymethacrylimide, polyacrylonitrile, polystyrene, polycarbonate, styrene-acrylonitrile copolymer, styrene-butadiene copolymer, styrene-ethylene/butylene-styrene copolymer, styrene-ethylene-butadiene copolymer, acrylonitrile-styrene-butadiene copolymer, styrene-maleic acid copolymer, or a combination thereof. According to an embodiment of the disclosure, the weight ratio of the compound having a structure represented by Formula (I) to the thermoplastic elastomer can be from about 1:3 to 3:1, such as from about 3:7 to 7:3. When the weight ratio of the compound having a structure represented by Formula (I) to the thermoplastic elastomer is too low, the adhesive layer prepared from the adhesive composition exhibits poor thermal resistance and chemical resistance. When the weight ratio of the compound having a structure represented by Formula (I) to the thermoplastic elastomer is too high, the adhesive layer prepared from the adhesive composition exhibits poor flexibility, thereby reducing the adhesion between the adhesive layer prepared from the adhesive composition and the liquid-crystal polymer (LCP).

According to an embodiment of the disclosure, in the adhesive composition, the epoxy resin can have a weight percentage from about 1 wt % to 10 wt %, such as from about 3 wt % to 7 wt %, based on the total weight of the compound having a structure represented by Formula (I) and the thermoplastic elastomer. When the weight percentage of the epoxy resin is too low, the adhesion between the adhesive layer prepared from the adhesive composition and the liquid-crystal polymer (LCP) is reduced. When the weight percentage of the epoxy resin is too high, a phase separation of the adhesive composition is observed, thereby increasing the dielectric constant and dielectric dissipation factor of the obtained adhesive layer. According to an embodiment of the disclosure, the epoxy resin can be bisphenol A epoxy resin, bisphenol F epoxy resin, bisphenol S epoxy resin, novolac epoxy resin, biphenyl epoxy resin, or cyclopentadiene epoxy resin.

According to embodiments of the disclosure, in the adhesive composition, the bismaleimide can have a weight percentage from about 4 wt % to 15 wt %, such as from about 6 wt % to 14 wt %, based on the total weight of the compound having a structure represented by Formula (I) and the thermoplastic elastomer. When the weight percentage of the bismaleimide is too low, the adhesive layer prepared from the adhesive composition exhibits low chemical resistance. When the weight percentage of the bismaleimide is too high, a phase separation of the adhesive composition is observed, thereby increasing the dielectric constant and dielectric dissipation factor of the obtained adhesive layer. According to embodiments of the disclosure, the bismaleimide employed in the adhesive composition of the disclosure can be completely dissolved in toluene at room temperature, wherein the weight ratio of the bismaleimide to the toluene is from about 0.8:1 to 1:0.8, such as 1:1. As a result, a phase separation of the adhesive composition is very slight or not observed, thereby increasing the processability of the adhesive composition. The bismaleimide has a structure represented by Formula (II)

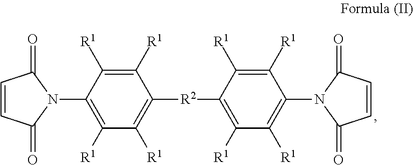

wherein R¹ is independently hydrogen, or C₁₋₆ alkyl group; and R² is C₁₋₆ alkylene group, or phenylene group. In addition, at least one R¹ of the bismaleimide having a structure represented by Formula (II) can be not hydrogen.

According to an embodiment of the disclosure, the adhesive composition of the disclosure can further include an additive, wherein the additive can be initiator, hardener, leveling agent, filler, colorant, defoamer, flame retardant, or a combination thereof. In addition, the additive can have a weight percentage from 0.1 wt % to 10 wt %, based on the total weight of the compound having a structure represented by Formula (I) and the thermoplastic elastomer.

According to an embodiment of the disclosure, the adhesive composition of the disclosure can further include a solvent in order to dissolve the compound having a structure represented by Formula (I), thermoplastic elastomer, epoxy resin, bismaleimide, and additives. Therefore, the above components can be dissolved in the solvent uniformly. The solvent can be propylene glycol monomethyl ether acetate (PGMEA), ethyl-2-ethoxy ethanol acetate, 3-ethoxy propionate, isoamyl acetate, benzene, toluene, xylene, cyclohexane, or a combination thereof.

According to an embodiment of the disclosure, the initiator can be peroxide initiator, such as benzoyl peroxide, 1,1-bis(tert-butylperoxy)cyclohexane, 2,5-bis(tert-butylperoxy)-2,5-dimethylcyclohexane, 2,5-bis(tert-butylperoxy)-2,5-dimethyl-3-cyclohexyne, bis(1-(tert-butylpeorxy)-1-methy-ethyl)benzene, tert-butyl hydroperoxide, tert-butyl peroxide, tert-butyl peroxybenzoate, cumene hydroperoxide, cyclohexanone peroxide, dicumyl peroxide, lauroyl peroxide, or a combination thereof.

According to an embodiment of the disclosure, the hardener can be imidazole compound, such as 2-undecylimidazole, 2-heptadecylimidazole, 2-methylimidazole, 2-ethyl-4-methylimidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecyl imidazolium trimeritate, 1-cyanoethyl-2-phenyl imidazolium trimeritate, 2-phenyl-4,5-dihydroxymethylimidazole, 2-phenyl-4-methyl-5-dihydroxymethylimidazole, or a combination thereof.

According to an embodiment of the disclosure, the flame retardant can be bromine-containing or phosphorous-containing flame retardant, and the filler can be organic powder or inorganic powder, such as Al(OH)₃, Al₂O₃, Mg(OH)₂, MnO₂, SiO₂, or polyimide powder.

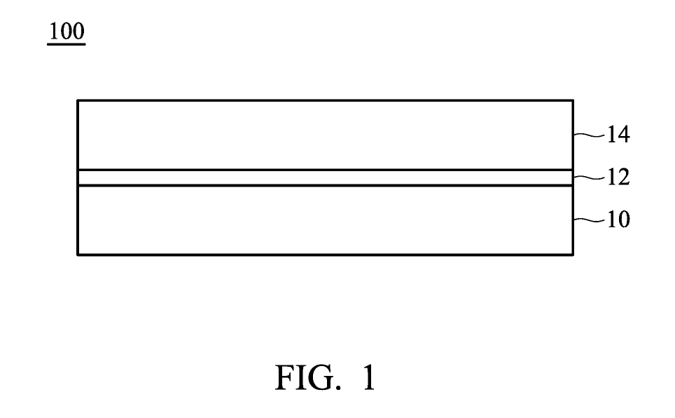

According to an embodiment of the disclosure, the disclosure also provides a composite substrate, such as a flexible printed circuit (FPC) board. As shown in FIG. 1, the composite substrate 100 can include a first substrate 10, an adhesive layer 12, and a second substrate 14, wherein the adhesive layer 12 disposed between the first substrate 10 and the second substrate 14, in order to combine the first substrate and the second substrate. According to an embodiment of the disclosure, the first substrate 10 and second substrate 14 can be liquid-crystal polymer (LCP) copper clad laminate board. According to an embodiment of the disclosure, the method for fabricating the composite substrate 100 includes the following steps. First, the adhesive composition of the disclosure is coated on a polyethylene terephthalate (PET) substrate, and then baked at 80° C. (for removing the solvent), obtaining a coating. Next, the coating is disposed between the first substrate and the second substrate, to obtain a stacked structure. Next, the stacked structure is laminated and cured at a specific temperature (such as a temperature of about 130° C. to 200° C., or such as about 180° C.), obtaining the composite substrate of the disclosure.

According to an embodiment of the disclosure, the adhesive composition includes the compound having a structure represented by Formula (I), thermoplastic elastomer, epoxy resin, and bismaleimide. The weight ratio of the compound having a structure represented by Formula (I) to the thermoplastic elastomer is from about 1:3 to 3:1. The epoxy resin can have a weight percentage from about 1 wt % to 10 wt %, based on the total weight of the compound having a structure represented by Formula (I) and the thermoplastic elastomer. The bismaleimide can have a weight percentage from about 4 wt % to 15 wt %, based on the total weight of the compound having a structure represented by Formula (I) and the thermoplastic elastomer. Therefore, the adhesive layer prepared from the adhesive composition exhibits improved thermal resistance, chemical resistance, and flexibility. Furthermore, the adhesion between the adhesive layer prepared from the adhesive composition and the liquid-crystal polymer (LCP) is improved, thereby reducing the dielectric constant and dielectric dissipation factor of the obtained composite substrate.

Below, exemplary embodiments are described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout

### Preparation of Adhesive Composition

### Example 1

30 parts by weight of Polyphenylene ether compound (1) (having a structure represented by

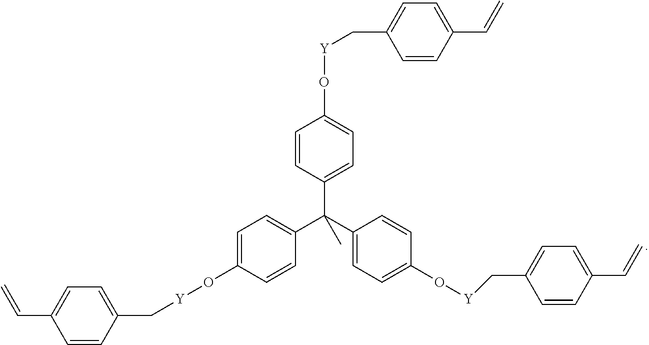

Y had repeat units

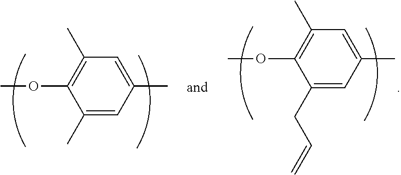

The ratio between

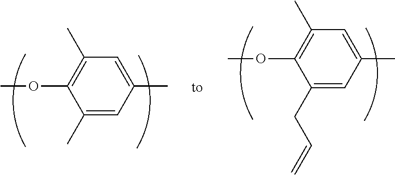

was 1:5. In addition, repeat units

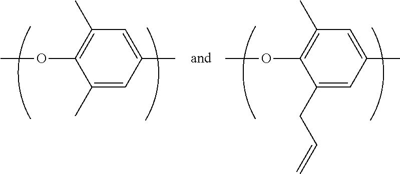

were arranged in an irregular or intermittent order. More specifically, Y was bonded to the oxygen moieties of the core structure

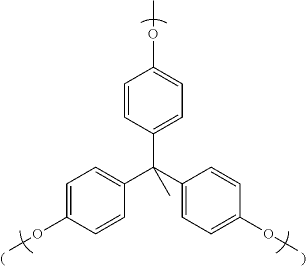

through the carbons in the benzene ring of the repeat units

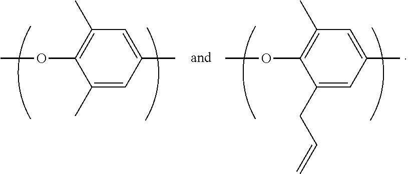

In addition, the oxygen moiety of the terminal repeat unit

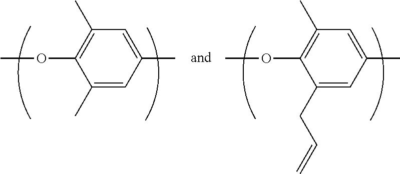

was bonded to the vinylbenzyl group. The polyphenylene ether compound had a number average molecular weight (Mn) of about 8304), 70 parts by weight of styrene-ethylene-butylene-styrene (SEBS) block copolyme (sold and manufactured by Kuraray with a trade No. of Septon 8007), 3 parts by weight of biphenyl epoxy resin (sold and manufactured by Nippon Kayaku co. ltd with a trade No. of NC-3000), 6 parts by weight of bismaleimide (having a structure represented by

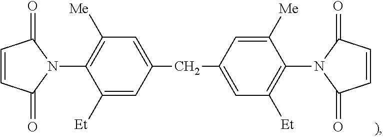 [SMILES: CCc1cc(Cc2cc(C)c(N3C(=O)C=CC3=O)c(CC)c2)cc(C)c1N1C(=O)C=CC1=O]

0.6 parts by weight of initiator (1,3-bis[3-(tert-butylperoxy)propyl]benzene, sold and manufactured by NOF Corporation with a trade No. of Perbutyl P), and 0.15 parts by weight of hardener (2-ethyl-4-methyl-imidazole (2E4MI)) were added into a reaction bottle. Next, toluene (as solvent) was added into the reaction bottle. After stirring completely, Adhesive composition (1) was obtained.

### Example 2

50 parts by weight of Polyphenylene ether compound (1), 50 parts by weight of styrene-ethylene-butylene-styrene block copolyme (sold and manufactured by Kuraray with a trade No. of Septon 8007), 5 parts by weight of biphenyl epoxy resin (sold and manufactured by Nippon Kayaku co. ltd with a trade No. of NC-3000), 10 parts by weight of bismaleimide (having a structure represented by

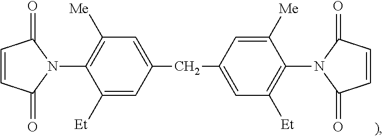 [SMILES: CCc1cc(Cc2cc(C)c(N3C(=O)C=CC3=O)c(CC)c2)cc(C)c1N1C(=O)C=CC1=O]

1 part by weight of initiator (1,3-bis[3-(tert-butylperoxy)propyl]benzene, sold and manufactured by NOF Corporation with a trade No. of Perbutyl P), and 0.25 parts by weight of hardener (2-ethyl-4-methyl-imidazole (2E4MI)) were added into a reaction bottle. Next, toluene (as solvent) was added into the reaction bottle. After stirring completely, Adhesive composition (2) was obtained.

### Example 3

70 parts by weight of Polyphenylene ether compound (1), 30 parts by weight of styrene-ethylene-butylene-styrene block copolyme (sold and manufactured by Kuraray with a trade No. of Septon 8007), 7 parts by weight of biphenyl epoxy resin (sold and manufactured by Nippon Kayaku co. ltd with a trade No. of NC-3000), 14 parts by weight of bismaleimide (having a structure represented by

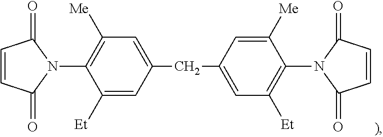 [SMILES: CCc1cc(Cc2cc(C)c(N3C(=O)C=CC3=O)c(CC)c2)cc(C)c1N1C(=O)C=CC1=O]

1.4 parts by weight of initiator (1,3-bis[3-(tert-butylperoxy)propyl]benzene, sold and manufactured by NOF Corporation with a trade No. of Perbutyl P), and 0.35 parts by weight of hardener (2-ethyl-4-methyl-imidazole (2E4MI)) were added into a reaction bottle. Next, toluene (as solvent) was added into the reaction bottle. After stirring completely, Adhesive composition (3) was obtained.

### Comparative Example 1

50 parts by weight of polyphenylene ether resin (sold and manufactured by Mitsubishi Gas Chemical Company Inc with a trade No. of OPE-2st), 50 parts by weight of styrene-ethylene-butylene-styrene block copolyme (sold and manufactured by Kuraray with a trade No. of Septon 8007), 5 parts by weight of biphenyl epoxy resin (sold and manufactured by Nippon Kayaku co. ltd with a trade No. of NC-3000), 10 parts by weight of bismaleimide (having a structure represented by

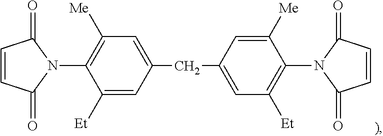 [SMILES: CCc1cc(Cc2cc(C)c(N3C(=O)C=CC3=O)c(CC)c2)cc(C)c1N1C(=O)C=CC1=O]

1 part by weight of initiator (1,3-bis[3-(tert-butylperoxy)propyl]benzene, sold and manufactured by NOF Corporation with a trade No. of Perbutyl P), and 0.25 parts by weight of hardener (2-ethyl-4-methyl-imidazole (2E4MI)) were added into a reaction bottle. Next, toluene (as solvent) was added into the reaction bottle. After stirring completely, Adhesive composition (4) was obtained.

### Comparative Example 2

100 parts by weight of polyphenylene ether resin (sold and manufactured by Mitsubishi Gas Chemical Company Inc with a trade No. of OPE-2st), 10 parts by weight of biphenyl epoxy resin (sold and manufactured by Nippon Kayaku co. ltd with a trade No. of NC-3000), 10 parts by weight of bismaleimide (having a structure represented by

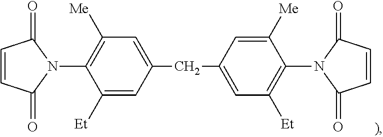 [SMILES: CCc1cc(Cc2cc(C)c(N3C(=O)C=CC3=O)c(CC)c2)cc(C)c1N1C(=O)C=CC1=O]

2 parts by weight of initiator (1,3-bis[3-(tert-butylperoxy)propyl]benzene, sold and manufactured by NOF Corporation with a trade No. of Perbutyl P), and 0.5 parts by weight of hardener (2-ethyl-4-methyl-imidazole (2E4MI)) were added into a reaction bottle. Next, toluene (as solvent) was added into the reaction bottle. After stirring completely, Adhesive composition (5) was obtained.

### Comparative Example 3

20 parts by weight of Polyphenylene ether compound (1), 80 parts by weight of styrene-ethylene-butylene-styrene block copolymer (sold and manufactured by Kuraray with a trade No. of Septon 8007), 2 parts by weight of biphenyl epoxy resin (sold and manufactured by Nippon Kayaku co. ltd with a trade No. of NC-3000), 4 parts by weight of bismaleimide (having a structure represented by

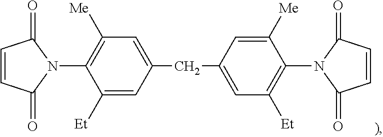 [SMILES: CCc1cc(Cc2cc(C)c(N3C(=O)C=CC3=O)c(CC)c2)cc(C)c1N1C(=O)C=CC1=O]

0.4 parts by weight of initiator (1,3-bis[3-(tert-butylperoxy)propyl]benzene, sold and manufactured by NOF Corporation with a trade No. of Perbutyl P), and 0.1 parts by weight of hardener (2-ethyl-4-methyl-imidazole (2E4MI)) were added into a reaction bottle. Next, toluene (as solvent) was added into the reaction bottle. After stirring completely, Adhesive composition (6) was obtained.

### Comparative Example 4

80 parts by weight of Polyphenylene ether compound (1), 20 parts by weight of styrene-ethylene-butylene-styrene block copolyme (sold and manufactured by Kuraray with a trade No. of Septon 8007), 8 parts by weight of biphenyl epoxy resin (sold and manufactured by Nippon Kayaku co. ltd with a trade No. of NC-3000), 16 parts by weight of bismaleimide (having a structure represented by

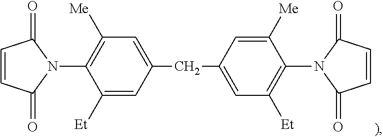 [SMILES: CCc1cc(Cc2cc(C)c(N3C(=O)C=CC3=O)c(CC)c2)cc(C)c1N1C(=O)C=CC1=O]

1.6 parts by weight of initiator (1,3-bis[3-(tert-butylperoxy)propyl]benzene, sold and manufactured by NOF Corporation with a trade No. of Perbutyl P), and 0.4 parts by weight of hardener (2-ethyl-4-methyl-imidazole (2E4MI)) were added into a reaction bottle. Next, toluene (as solvent) was added into the reaction bottle. After stirring completely, Adhesive composition (7) was obtained.

Table 1 shows the components and amount of the adhesive composition disclosed in Examples 1 to 3 and Comparative Examples 1 to 4.

TABLE 1

| | Adhesive composition | | | | | | |
|---|---|---|---|---|---|---|---|
| | Example 1 | Example 2 | Example 3 | Comparative | Comparative | Comparative | Comparative |
| Polyphenylene | 30 | 50 | 70 | 0 | 0 | 20 | 80 |
| ether compound (1) | | | | | | | |
| (parts by weight) | | | | | | | |
| OPE-2st | 0 | 0 | 0 | 50 | 100 | 0 | 0 |
| (parts by weight) | | | | | | | |
| SEBS(parts by | 70 | 50 | 30 | 50 | 0 | 80 | 20 |
| weight) | | | | | | | |
| NC-3000(parts by | 3 | 5 | 7 | 5 | 10 | 2 | 8 |
| weight) | | | | | | | |
| BMI(parts by | 6 | 10 | 14 | 10 | 10 | 4 | 16 |
| weight) | | | | | | | |
| Perbutyl P(parts by | 0.6 | 1 | 1.4 | 1 | 2 | 0.4 | 1.6 |
| weight) | | | | | | | |
| 2E4MI(parts by | 0.15 | 0.25 | 0.35 | 0.25 | 0.5 | 0.1 | 0.4 |
| weight) | | | | | | | |

### Preparation and Measurement of Layers

### Example 4

The adhesive compositions of Examples 1 to 3 and Comparative Examples 1 to 2 were coated individually on PET substrates, obtaining coatings. Next, the coatings were baked at 180° C. for 60 min, obtaining Layers (1) to (5). Next, the flexibility, dielectric constant, dielectric dissipation factor, glass transition temperature (Tg), chemical resistance, and solder resistance of Layers (1) to (5) were measured, and the results are shown in Table 2. The flexibility was determined according to ASTM D 790. The dielectric constant and dielectric dissipation factor were measured at 10 GHz by microwave dielectrometer (sold by AET company). The glass transition temperature (Tg) was measured by dynamic mechanical spectrometer (DMA). In addition, the chemical resistance was determined by immersing the test sample in toluene. When no expansion of the test sample was observed, the chemical resistance was evaluated as “Pass”.

TABLE 2

| | Adhesive composition | | | | |
|---|---|---|---|---|---|
| | | | | Layer (4) | Layer (5) |
| | Layer (1) | Layer (2) | Layer (3) | Comparative | Comparative |
| | Example 1 | Example 2 | Example 3 | example 1 | example 2 |
| flexibility | Excellent | Excellent | Excellent | Excellent | poor |
| dielectric constant (Dk) | 2.5 | 2.6 | 2.5 | 2.4 | — |
| dielectric dissipation | 0.003 | 0.004 | 0.004 | 0.003 | — |
| factor (Df) | | | | | |
| glass transition | 177 | 186 | 198 | 176 | — |
| temperature (Tg) | | | | | |
| chemical resistance | Pass | Pass | Pass | Expension | — |

As shown in Table 2, since the branched Polyphenylene ether compound (1) was replaced with the linear polyphenylene ether (bis(vinylbenzyl) ether) resin, the obtained Layer (4) (prepared from Adhesion composition (4) of Comparative Example 1) was expended when being immersed in toluene. Therefore, in comparison with Layer (2) (prepared from Adhesion composition (2) of Example 2), Layer (4) exhibits inferior chemical resistance. Furthermore, since Adhesion composition (5) did not include the thermoplastic elastomer (SEBS block copolyme), Layer (5) exhibits a relatively high friability and did not pass the flexibility test. Conversely, since Adhesion compositions (1) to (3) employ the branched polyphenylene ether compound and the thermoplastic elastomer (SEBS block copolyme) which are present in a specific ratio, Layers (1) to (3) prepared by Adhesive compositions (1) to (3) of Examples 1 to 3 exhibits relatively high flexibility.

### Preparation of Composite Substrate and Properties Measurement of Composite Substrate

### Example 5

The adhesive compositions of Examples 1 to 3 and Comparative Examples 1, 3, and 4 were coated individually on PET substrates, and then the PET substrates were removed to obtain coatings. Next, the coatings were baked at 80° C. for removing solvent. Next, each coating was disposed between two liquid-crystal polymer (LCP) copper clad laminate boards, and the obtained stacked structure was subjected to a lamination process and then baked at 180° C. After baking, the coating was cured to form an adhesive layer, obtaining Composite substrates (1) to (6). The adhesion between the two liquid-crystal polymer (LCP) copper clad laminate boards of Composite substrates (1) to (6) were measured according to ASTM D 257. The solder resistance of Composite substrates (1) to (6) was measured according to ASTM D 543 (at 288° C.). The results are shown in Table 3.

TABLE 3

| | Adhesive composition | | | | | |
|---|---|---|---|---|---|---|
| | | | | Composite | Composite | Composite |
| | Composite | Composite | Composite | substrate (4) | substrate (5) | substrate (6) |
| | substrate (1) | substrate (2) | substrate (3) | Comparative | Comparative | Comparative |
| | Example 1 | Example 2 | Example 3 | Example 1 | Example 3 | Example 4 |
| adhesion | 12 | 11 | 10 | 8 | 10 | 7 |
| (N/cm) | | | | | | |
| solder | Pass | Pass | Pass | Pass | Fail | Pass |
| resistance | | | | | (popcorn was | |
| | | | | | observed) | |

The adhesive compositions of Examples 1 to 3 and Comparative Examples 1, 3, and 4 were coated individually on PET substrates, and then the PET substrates were removed to obtain coatings. Next, the coatings were baked at 80° C. for removing solvent. Next, each coating was disposed between a liquid-crystal polymer (LCP) copper clad laminate board and a copper clad substrate, and the obtained stacked structure was subjected to a lamination process and then baked at 180° C. After baking, the coating was cured to form an adhesive layer, obtaining Composite substrates (7) to (12). The adhesion between the copper clad substrate and the liquid-crystal polymer (LCP) copper clad laminate board of Composite substrates (7) to (12) was measured according to ASTM D 257. The results are shown in Table 4.

TABLE 4

| | adhesive composition | | | | | |
|---|---|---|---|---|---|---|
| | | | | Composite | Composite | Composite |
| | Composite | Composite | Composite | substrate (10) | substrate (11) | substrate (12) |
| | substrate (7) | substrate (8) | substrate (9) | Comparative | Comparative | Comparative |
| | Example 1 | Example 2 | Example 3 | Example 1 | Example 3 | Example 4 |
| adhesion | 14 | 12 | 12 | 11 | 11 | 9 |
| (N/cm) | | | | | | |

As shown in Table 3 and Table 4, since Adhesion compositions (1) to (3) employ the branched polyphenylene ether compound and the thermoplastic elastomer (SEBS block copolyme) which are present in a specific ratio, the composite substrates prepared by Adhesion compositions (1) to (3) of Examples 1 to 3 can pass the solder resistance test. Furthermore, the composite substrates prepared by Adhesion compositions (1) to (3) of Examples 1 to 3 exhibit relatively high adhesion between LCP and LCP and relatively high adhesion between LCP and copper clad substrate.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An adhesive composition, comprising:
a compound having a structure represented by Formula (I)
(Z—Y₃X Formula (I)
, wherein X is 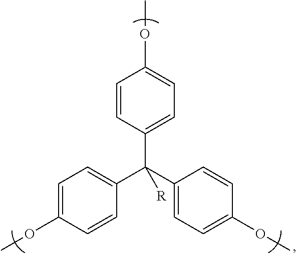
R is hydrogen, or C₁₋₆ alkyl group; each Y is independently a moiety polymerized by at least two different phenolic compounds; and each Z is independently hydrogen, acryloyl group, allyl group, vinylbenzyl group, epoxypropyl group, methylacryloyl group, propargyl group, or cyanoallyl group;
a thermoplastic elastomer, wherein the weight ratio of the compound having a structure represented by Formula (I) to the thermoplastic elastomer is from 1:3 to 3:1;
an epoxy resin; and
a bismaleimide.

2. The adhesive composition as claimed in claim 1, wherein the at least two different phenolic compounds individually have at least one functional group, wherein the functional group is C₁₋₆ alkyl group, or allyl group.

3. The adhesive composition as claimed in claim 1, wherein Y is a moiety prepared by polymerizing 2,6-dimethylphenol and 2-allyl-6-methylphenol.

4. The adhesive composition as claimed in claim 1, wherein Y is 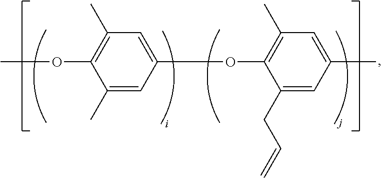
wherein i is a positive integer, j is a positive integer, and the sum of i and j is from 6 to 300, and repeat units 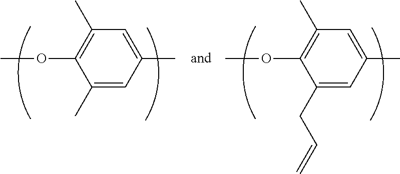
are arranged in a random or block fashion.

5. The adhesive composition as claimed in claim 1, wherein Z is hydrogen, epoxypropyl group, vinylbenzyl group, or methacryloyl group.

6. The adhesive composition as claimed in claim 1, wherein the compound having a structure represented by Formula (I) have a number average molecular weight from 600 to 12000.

7. The adhesive composition as claimed in claim 1, wherein the thermoplastic elastomer is polymethacrylate, polymethyl methacrylate, polyacrylimide, polymethacrylimide, polyacrylonitrile, polystyrene, polycarbonate, styrene-acrylonitrile copolymer, styrene-butadiene copolymer, styrene-ethylene/butylene-styrene copolymer, styrene-ethylene-butadiene copolymer, acrylonitrile-styrene-butadiene copolymer, styrene-maleic acid copolymer, or a combination thereof.

8. The adhesive composition as claimed in claim 1, wherein the epoxy resin has a weight percentage from 1 wt % to 10 wt %, based on the total weight of the compound having a structure represented by Formula (I) and the thermoplastic elastomer.

9. The adhesive composition as claimed in claim 1, wherein the epoxy resin is bisphenol A epoxy resin, bisphenol F epoxy resin, bisphenol S epoxy resin, novolac epoxy resin, biphenyl epoxy resin, or cyclopentadiene epoxy resin.

10. The adhesive composition as claimed in claim 1, wherein the bismaleimide has a weight percentage from 4 wt % to 15 wt %, based on the total weight of the compound having a structure represented by Formula (I) and the thermoplastic elastomer.

11. The adhesive composition as claimed in claim 1, wherein the bismaleimide is completely dissolved in toluene at room temperature, wherein the weight ratio of the bismaleimide to the toluene is from about 0.8:1 to 1:0.8.

12. The adhesive composition as claimed in claim 11, wherein the bismaleimide has a structure represented by Formula (II) 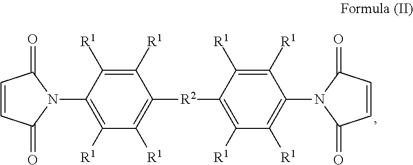
wherein R¹ is independently hydrogen, or C₁₋₆ alkyl group; and R² is C₁₋₆ alkylene group, or phenylene group.

13. The adhesive composition as claimed in claim 12, wherein at least one R¹ is not hydrogen.

14. The adhesive composition as claimed in claim 1, further comprising:
an additive.

15. The adhesive composition as claimed in claim 14, wherein the additive is initiator, hardener, leveling agent, filler, colorant, defoamer, flame retardant, or a combination thereof.

16. The adhesive composition as claimed in claim 14, wherein the additive has a weight percentage from 0.1 wt % to 10 wt %, based on the total weight of the compound having a structure represented by Formula (I) and the thermoplastic elastomer.

17. A composite substrate, comprising:
an adhesive layer, wherein the adhesive layer is a cured product of the adhesive composition as claimed in claim 1; and
a first substrate, wherein the adhesive layer is disposed on the first substrate.

18. The composite substrate as claimed in claim 17, further comprising:
a second substrate, wherein the adhesive layer is disposed between the first substrate and the second substrate, in order to combine the first substrate and the second substrate.

19. The composite substrate as claimed in claim 18, wherein the first substrate and the second substrate are a liquid-crystal polymer copper clad laminate board.

20. The composite substrate as claimed in claim 17, wherein the composite substrate is a flexible printed circuit (FPC) board.
